(19) United States
(12) Patent Application Publication
(10) Pub. No.: US 2017/0175260 A1
(43) Pub. Date: Jun. 22, 2017

(54) CERAMIC/POLYMER COMPOSITE MATERIAL AND METHOD FOR FABRICATING THE SAME

(71) Applicant: INDUSTRIAL TECHNOLOGY RESEARCH INSTITUTE, Hsinchu (TW)

(72) Inventors: Wei-Tien Hsiao, Zhudong Township (TW); Ming-Sheng Leu, Zhudong Township (TW); Hong-Jen Lai, Hsinchu City (TW); Chang-Chih Hsu, Hsinchu City (TW)

(73) Assignee: INDUSTRIAL TECHNOLOGY RESEARCH INSTITUTE, Hsinchu (TW)

(21) Appl. No.: 14/981,325

(22) Filed: Dec. 28, 2015

(30) Foreign Application Priority Data
Dec. 16, 2015 (TW) 104142314

(51) Int. Cl. C23C 16/06; C23C 6/00; C23C 4/134; C23C 14/14; C23C 18/31

(52) U.S. Cl. CPC C23C 16/06; C23C 14/14; C23C 18/31; C23C 4/134; C23C 6/00

(57) ABSTRACT

A ceramic/polymer composite material includes a polymer layer, a metal interface layer and a ceramic layer. The polymer layer has a polymer surface and at least one recess formed on the polymer surface. The metal interface layer that has a first surface and a second surface opposite to the first surface conformally covers on the polymer layer, wherein at least portions of the first surface and the second surface extend into the recess. The ceramic layer is disposed on the metal interface layer.

This application claims the benefit of Taiwan application Serial No. 104142314, filed Dec. 16 2015, the disclosure of which is incorporated by reference herein in its entirety.

### TECHNICAL FIELD

The technical field relates to a hetero-junction material and method for fabricating the same, and more particularly to a ceramic/polymer composite material and method for fabricating the same.

### BACKGROUND

A composite material is a synthetic materials which has a multi-phase and 3D structure. The individual components remain separate and distinct within the finished structure and exist an obvious interface. For example, a composite that is made from ceramic and polymer has superiority of high strength, high toughness, light weight, corrosion resistance and abrasion resistance. Therefore, it has been widely used in the motor industry, electronics industry, aerospace industry, automobile industry, shipbuilding industry, and sports equipment.

However, since ceramic/polymer composite material has a poor bonding ability between two components, it's easy to produce shedding or stratified by external mechanical stress or thermal stress. Moreover, ceramic process is generally performed under high temperature so as to easy to damage the interface between the ceramic and polymer materials and the impact of the follow-up process and the final product yield.

Therefore, a novel method for fabricating the same and applications thereof is desired for improving the performance of the ceramic/polymer composite material

### SUMMARY

In accordance with the disclosure, one embodiment of the present disclosure is directed to a ceramic/polymer composite material comprising a polymer layer, a metal interface layer and a ceramic layer. The polymer layer has a polymer surface and at least one recess formed on the polymer surface. The metal interface layer that has a first surface and a second surface opposite to the first surface conformally covers on the polymer layer, wherein at least portions of the first surface and the second surface extend into the recess. The ceramic layer is disposed on the metal interface layer.

According to another embodiment, a method for fabricating a ceramic/polymer composite material is provided. The method comprises following steps: A polymer layer is provided. A surface process is performed to form at least one recess on the surface of the polymer layer. A metal interface layer conformally covering on the polymer layer is formed, wherein the metal interface layer having a first surface and a second surface opposite to the first surface, and at least portions of the first surface and the second surface extend into the recess. Then, a ceramic layer is formed over the metal interface layer.

### BRIEF DESCRIPTION OF THE DRAWINGS

The above and other aspects of the invention will become better understood with regard to the following detailed description.

FIG. 1 is a flowchart of a method for fabricating a ceramic/polymer composite material according to an embodiment of the present disclosure;

FIG. 2A-2D are structural cross-sectional views of the processes for fabricating the ceramic/polymer composite material according to an embodiment of the present disclosure;

FIG. 3 is a 3D structural perspective of an inter-body fusion device using the ceramic/polymer composite material according to an embodiment of the disclosure; and

FIG. 4 is a structural diagram of the inter-body fusion device of FIG. 3 used in human vertebra according to an embodiment of the disclosure.

### DETAILED DESCRIPTION

The embodiments disclosed in the present specification relate to a ceramic/polymer composite material, a method for fabricating the same and applications thereof capable of resolving the problems encountered in the interface between ceramic and polymer materials and derived from the poor binding ability of the interface which causes the ceramic material to shed and stratify. For the above objects, features and advantages of the present disclosure to be clearly understood, a method for fabricating a ceramic/polymer composite material with hetero-junction, is disclosed in an exemplary embodiment, and detailed descriptions are disclosed below with accompanying drawings.

However, it should be noted that the embodiments and methods exemplified in the present disclosure are not for limiting the scope of protection of the present disclosure. The present disclosure can be implemented by using other features, methods and parameters. Exemplary embodiments are disclosed for exemplifying the technical features of the present disclosure, not for limiting the scope of protection of the present disclosure. Anyone who is skilled in the technology field of the disclosure can make necessary modifications or variations according to the descriptions of the present specification without violating the spirit of the present disclosure. For the same components common to different embodiments and drawings, the same numeric designations are retained.

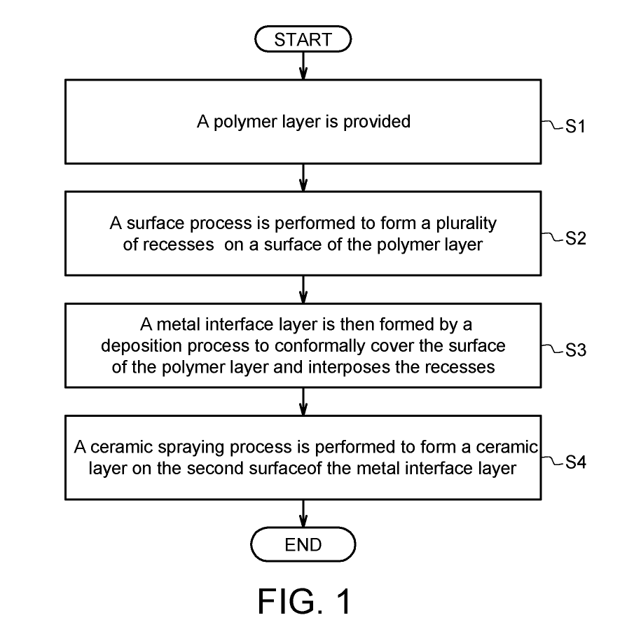

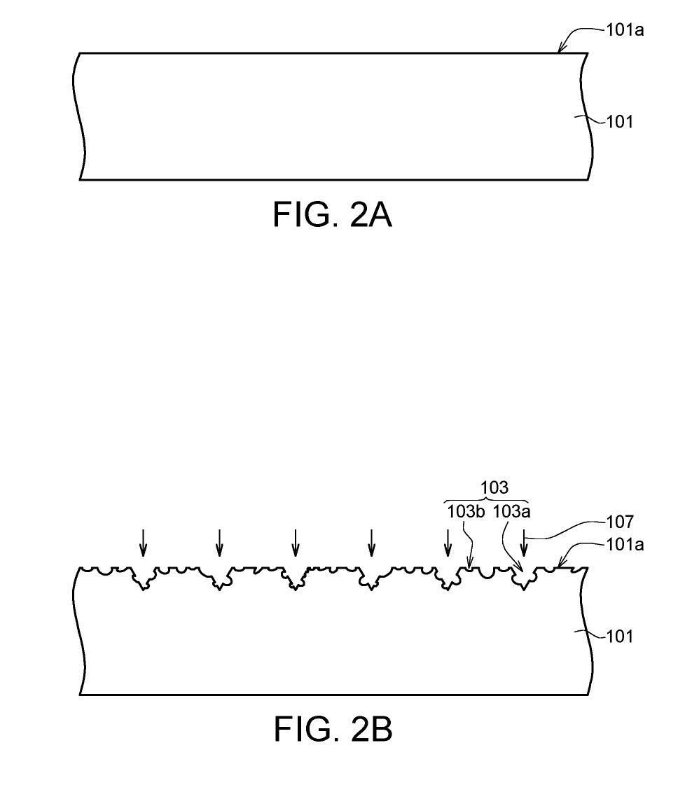

FIG. 1 is a flowchart of a method for fabricating a ceramic/polymer composite material 100 according to an embodiment of the present disclosure. FIG. 2A to FIG. 2D are structural cross-sectional views of the method for fabricating a ceramic/polymer composite material 100. Referring to FIG. 1, the method for fabricating the ceramic/polymer composite material 100 begins at step S1. Firstly, a polymer layer 101 is provided (as indicated in FIG. 2A).

The polymer layer 101 can be formed of a polymer compound using a plasticized polymer such as plastic, silicone, synthetic rubber, synthetic fibers, synthetic paint or adhesive as the base, or a natural polymer compound comprising cellulose, starch, and protein.

In some embodiments of the present disclosure, the polymer layer 101 can be formed by performing injection, pultrusion, membrane pressing, thermal pressing, blow molding, molding, filament winding, prepreg material laminating, transferring, foaming, casting, or lamination on a thermoplastic plastic, such as polyethylene (PE), polypropylene (PP), polystyrene (PS), polymethyl methacrylate (PMMA), polyvinyl chloride (PVC), nylon (Nylon), polycarbonate (PC), polyurethane (PU), polytetrafluoroethylene (PTFE), polyethylene terephthalate (PET, PETE), or a thermosetting plastic, such as epoxy, phenolic, polyimide, melamine formaldehyde resin.

In the present embodiment, the properties of the polymer layer 101 are preferably similar to that of human bones. For example, the materials of polymer layer 101 are selected from the group consisting of polyether ether ketone (PEEK), carbon reinforced (PEEK), polyetherketoneketone (PEKK) and polyaryletherketone (PAEK). In one embodiment, the polymer layer 101 has an elastic modulus substantially ranging from 2 Gpa to 22 Gpa.

It should be noted that the polymer layer 101 used in the present disclosure is not limited thereto, and any polymer materials suitable for contacting ceramic are within the spirit of the present disclosure.

Refer to step S2, a surface process 107 is performed to form a plurality of recesses 103 on a surface 101a of the polymer layer 101, wherein each recess 103 has a depth substantially ranging from 1 μm to 100 μm. In some embodiments of the present disclosure, the surface process 107 removes a part of the polymer layer 101 by way of CNC processing, laser surface treatment, plasma surface treatment, etching or a combination thereof to form a plurality of grooves 103a extending into the polymer layer 101 from the surface 101a.

For example, in one embodiment of the disclosure, the surface process 107 is performed by using pulsed laser with a pulse width of 1 ns to form a plurality of grooves 103a with size controllable and directional arrangement on the surface 101a of the polymer layer 101, so as to form an array pattern (not illustrated) on the surface of the polymer layer, wherein each groove 103a has a depth preferable substantially ranging from 20 μm to 100 μm.

In addition, the surface process can be a sand blasting treatment. For example, after forming the groove 103a array patterns, the sand blasting treatment uses a wind pressure substantially ranging from 1 Kg/mm² to 5 Kg/mm² to drive chemical non-active micro-particles such as aluminum oxide (Al₂O₃) particles and silicon dioxide (SiO₂) particles and so on (not illustrated) to physically collide with the surface 101a of the polymer layer 101, so as to form a plurality of cavities 103b with size controllable and anisotropic arrangement on the surface 101a of the polymer layer 101. The depth of each cavity 103b preferably ranges from 1 μm to 10 μm. Since the polymer layer 101 is collided by chemical non-active micro-particles, a compact dense area (not illustrated) is normally formed under the surface 101a of the polymer layer 101 after the sand blasting treatment is performed.

It should be noted that the recess 103 formed by surface process 107 is not limited thereto. For example, in some embodiments of the disclosure, the recess 103 formed by surface process 107 can be an array pattern formed of a plurality of grooves 103a. In another embodiments, the recess 103 can be a plurality of anisotropic cavities 103b using a sand blasting treatment. In some embodiments of the disclosure, the recesses 103 can be arranged in an irregular or regular manner to form a microstructure array pattern (not illustrated).

Referring to step S3, a metal interface layer 102 is then formed by a deposition process 104 to conformally cover the surface 101a of the polymer layer 101 and interposes the recesses 103 (as indicated in FIG. 2C). The metal interface layer 102 has a first surface 102a and a second surface 102b opposite to the first surface 102a. The first surface 102a contacts the surface 101a of the polymer layer 101, and at least portions of the first surface 102a and the second surface 102b extend into the recesses 103.

In some embodiments of the present disclosure, the thickness of the metal layer 102, measured from the surface 101a of the polymer layer 101, substantially ranges from 0.1 μm to 10 μm. A part of the metal interface layer 102 conformally cover side wall of the recess 103, and the first surface 102a and the second surface 102b completely extend into interior of the recesses 103. In other words, the metal interface layer 102 is not completely filled in the recesses 103 of the polymer layer 101. The thickness of the metal interface layer 102 is not limited thereto. In some embodiments of the present disclosure, the thickness of the metal interface layer 102 can be substantial completely filled in the recesses 103, and the second surface 102b of the metal interface layer 102 can be substantially located above the opening of the recess 103.

The deposition process 104 may comprise (but not limited to) physical vapor deposition (PVD), chemical vapor deposition (CVD), electroplating, electroless plating, powder plasma spray, powder plasma spraying, casting, curing colloidal solution or a combination thereof. The metal interface layer 102 can be a single- or multi-layered structure. For example, in some embodiments of the present disclosure, the metal interface layer 102 comprises at least one layer of metal film formed of titanium (Ti), gold (Au), titanium nitride (TiN), titanium-aluminum-vanadium alloy (Ti-6Al-4V), cobalt-chromium alloy (Co—Cr), stainless steel (SUS 316L), titanium nitride-aluminum-vanadium, or a combination thereof.

In the present embodiment, the metal interface layer 102 is formed by using the high power ion plating process (such as arc ion plating process) in conjunction with the synthetic powder granulation technology. A low temperature (such as 150° C.) air plasma spray (APS) is performed on a titanium metal powder so as to form at least one layer of titanium metal coating on the surface 101a of the polymer layer 101. In one preferable embodiment of the disclosure, one or multiple layer of titanium metal film is formed by using gradient layer deposition, and has a thickness substantially larger than 1 μm.

Since the atoms of the titanium metal have smaller particles, thus the thermal energy required for forming the particles with high energy (>20 eV) and high ionization (>90%) during the melting process can be reduced. Therefore, the surface temperature (<120° C.) of the polymer layer 101 during the plating process can be reduced, the damage caused by the melting powder colliding with the surface 101a of the polymer layer 101 can be reduced, and the adhesion (binding capacity) between the metal interface layer 102 and the polymer layer 101 can be enhanced.

Moreover, the presence of the metal interface layer 102 which has properties of heat dissipation and thermal buffering can avoid the heat being accumulated on the surface 101a of the polymer layer 101 in subsequent process. When the thickness of the metal interface layer 102 reaches a certain level, such as greater than 10 μm, the temperature on the surface 101a of the polymer layer 101 can be reduced to be below the melting point thereof to avoid thermal stress being concentrated in subsequent process and damaging the polymer layer 101. Besides, the titanium metal film which conformally covers on the side wall of the recess 103 of the polymer layer 101 can uniformly disperse the mechanic stress applied on the polymer layer 101 via the metal interface layer 102, so as to avoid the metal interface layer 102 and the polymer layer 101 from being peeled off by an impact of external force.

Referring to step S4, the ceramic/polymer composite material 100 is completely prepared after a ceramic spraying process 105 is performed to form a ceramic layer 106 on the second surface 102b of the metal interface layer 102 (as indicated in FIG. 2D). In some embodiments of the present disclosure, the surface ceramic spraying process can be ceramic spraying melting process. That is to say, ceramic material (such as hydroxyapatite (HA), aluminum oxide (Al₂O₃), titanium oxide (TiO₂), tricalcium diphosphate (Ca₃(PO₄)₂), zirconium oxide (ZrO₂) or a combination thereof) is melted by guilding an energy beam (such as laser, electron beam, arc, plasma, electromagnetic conduction etc.). For example, the ceramic material is melted by using selective laser melting (SLM), electron beam melting (EBM) or a combination thereof. A ceramic layer 106 having a thickness substantially ranging from 10 μm to 500 μm is formed by spraying the aforementioned melted ceramic material on the second surface 102b of the metal interface layer 102.

In the present embodiment, the hydroxyapatite having the purity larger than 99% and the grain size substantially ranging from 5 μm to 70 μm is melted by using selective laser sintering (SLS). The melted material is formed on the metal interface layer by importing carrier gas such as argon with fluid rate of substantially ranging from 20 l/min to 100 l/min, hydrogen with fluid rate of substantially ranging from 1 l/min to 20 l/min and power carrier gas with fluid rate of substantially ranging from 1 l/min to 5 l/min. In this embodiment, the melted hydroxyapatite is sprayed by using argon gas or nitrogen gas to the second surface 102b on the metal interface layer 102 to form the ceramic layer 106 on the second surface 102b of the metal interface layer, wherein the thickness of the ceramic layer 106 substantially ranges larger than 50 μm.

In one embodiment, the ceramic layer 106 can be a porous structure and has a porosity substantially ranging from 1% to 30%. In one embodiment, the density of the ceramic layer 103 substantially ranges from 70.0% to 99%. Since the ceramic layer 106 has superior biocompatibility, the ceramic/polymer composite material 100 for medical application will induce tissue cells to grow on the porous structure of the ceramic layer 106 and can be fused with the tissues and will not be peeled off the implanted tissues.

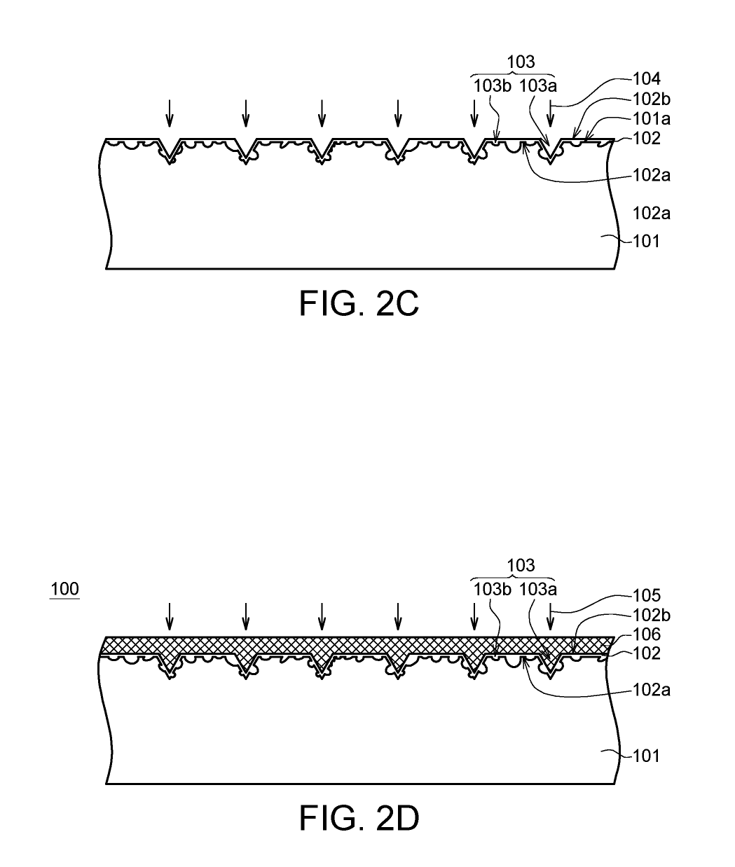

The ceramic/polymer made of aforementioned fabrication can be used to the application of bone screws, spinal fixation, inter-body fusion devices and artificial joints (not limited thereto). Referring to FIG. 3, FIG. 3 is a 3D structural perspective of an inter-body fusion device 300 using the ceramic/polymer composite material 100 according to an embodiment of the disclosure. The inter-body fusion device 300 comprises a body 301, a first metal interface layer 302, a second metal interface layer 303, a first osseo-integration layer 304 and a second osseo-integration layer 305.

The body 301 at least comprises the polymer layer 101 constituting the ceramic/polymer composite material 100. For example, in some embodiments of the present disclosure, the body 301 can be a bulk formed of a material identical to that for forming the polymer layer 101. In some embodiments of the present disclosure, the body 301 can be a carrying substrate formed of other materials, and the polymer layer 101 is fixed on the top surface and the bottom surface of the carrying substrate (not illustrated) by way of attachment, latching, thermal pressing, or assembly using fasteners, slide slots, bolts, and screw locks. In the present embodiment, the body 301 is a bulk formed of a polymer comprising polyether ether ketone (PEEK), and has an elastic modulus similar to human bone tissues. Thus when the ceramic/polymer composite material 100 is applied to human bone tissues the problems derived from stress shielding effect can be avoided.

The first metal interface layer 302 and the second metal interface layer 303, respectively formed on the upper and lower surfaces of the body 301 serving as the metal interface layer 102 of FIG. 2D, are tightly bonded to the body 301, and act as a thermal dissipation layer and a buffer layer to avoid the polymer layer 101 of the body 301 from being damaged by the thermal stress generated by the subsequent processes. In the present embodiment, the structure, materials and formation method of the first interface layer 302 and the second interface layer 303 are exactly the same as that of the interface layer 102 of the ceramic/polymer composite material 100, and the similarities are not redundantly repeated here.

The first osseo-integration layer 304 and the second osseo-integration layer 305 are respectively formed outside the first metal interface layer 302 and the second metal interface layer 303, whereby the first metal interface layer 302 is disposed between the body 301 and the first osseo-integration layer 304, and the second metal interface layer 303 is disposed between the body 301 and the second osseo-integration layer 305. In the present embodiment, since the structures, materials and formation method of the first osseo-integration layer 304 and the second osseo-integration layer 304 are exactly the same as that of the ceramic layer 106 of the ceramic/polymer composite material 100, thus the first osseo-integration layer 304 and the second osseo-integration layer 305 can be directly sprayed and cured on the first metal interface layer 302 and the second metal interface layer 303 to form a multi-layer composite structure with the body 301.

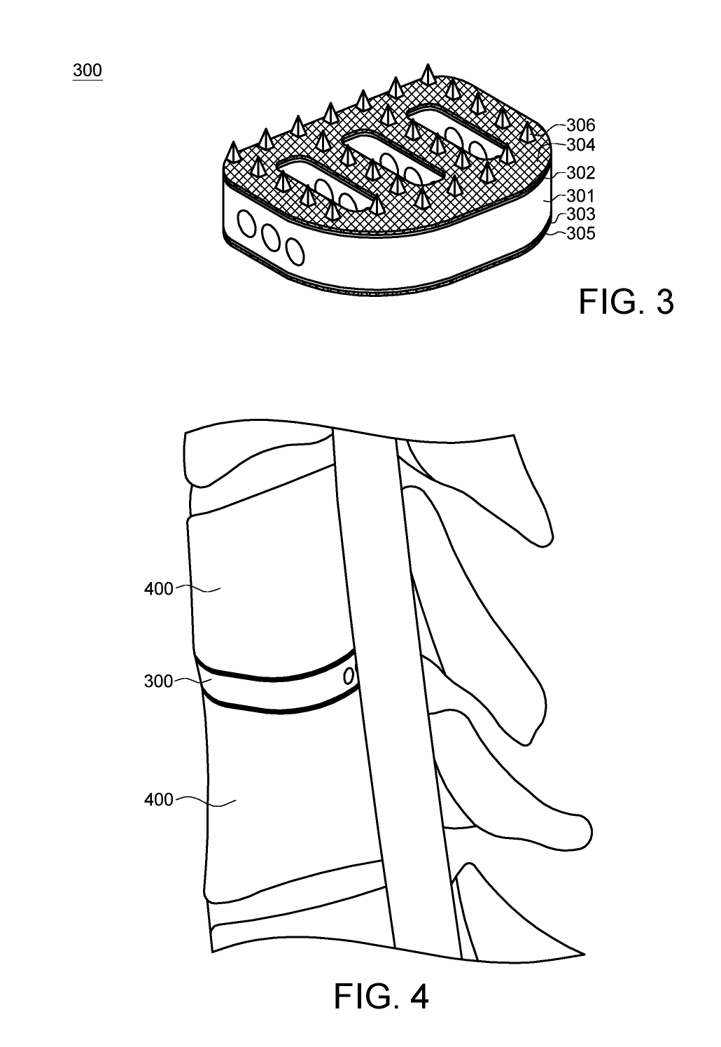

Referring to FIG. 4, a structural diagram of the inter-body fusion device 300 of FIG. 3 used in human vertebrae 400 according to an embodiment of the present disclosure is shown. The intervertebral disc 300 is implanted between two adjacent vertebrae 400. In some embodiments of the present disclosure, the inter-body fusion device 300 further comprises a plurality of occlusal teeth 306 disposed on a surface of the first osseo-integration layer 304 and the second osseo-integration layer 305 away from the first metal interface layer 302 and the second metal interface layer 303 for improving the security of the inter-body fusion device 300 implanted between the two adjacent vertebrae 400.

In accordance with the above disclosure, a ceramic/polymer composite material 100 with hetero-junction, a method for fabricating the same and applications thereof are disclosed. Firstly, a metal interface layer 102 is formed on the polymer layer 101 for contacting the polymer layer 101, wherein at least one recess 103 formed on the surface 101a of the polymer layer 101. The metal interface layer 102 that has a first surface 102a and a second surface 102b opposite to the first surface conformally covers on the polymer layer 101, wherein at least portions of the first surface 102a and the second surface 102b extend into the recess 103. Then, a porous structure ceramic layer is formed on the metal interface layer by using melting spray process.

Since the metal interface layer 102 can be formed on the polymer layer 101 by a low temperature deposition technology to avoid the thermal stress concentrated in the subsequent processes from penetrating and damaging the polymer layer 101, thus heterogeneous materials, such as a ceramic layer and a polymer layer, can be bonded together, and the ceramic/polymer composite material 100, which approximates the nature of human tissues and has excellent developable properties and biocompatibility, can be fabricated. The ceramic/polymer composite material 100 can be used in the inter-body fusion device 300 for inducing bone cells to grow, such that the inter-body fusion device 300 can be integrated with adjacent vertebrae 400 without peeling off. Moreover, since the polymer material and the adjacent vertebrae has similar elastic modulus, thus stress shielding effect occurs on the well-known material that is formed of one single material can be avoided.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A ceramic/polymer composite material, comprising:
a polymer layer having a polymer surface and at least one recess formed on the polymer surface;
a metal interface layer having a first surface and a second surface opposite to the first surface and conformally covering on the polymer layer, wherein at least portions of the first surface and the second surface extending into the recess; and
a ceramic layer disposed on the metal interface layer.

2. The ceramic/polymer composite material as claimed in claim 1, wherein the first surface contacts the polymer layer, and the second surface contacts the ceramic layer.

3. The ceramic/polymer composite material as claimed in claim 1, wherein the recess has a depth substantially ranging from 1 μm to 100 μm.

4. The ceramic/polymer composite material as claimed in claim 3, wherein the at least one recess comprises a plurality of grooves extending downwards from the polymer surface and laterally extending along one direction and each groove has a depth substantially ranging from 20 μm to 100 μm.

5. The ceramic/polymer composite material as claimed in claim 3, wherein the at least one recess comprises a plurality of anisotropic cavities formed on the polymer surface, and each anisotropic cavity has a depth substantially ranging from 1 μm to 10 μm.

6. The ceramic/polymer composite material as claimed in claim 1, wherein the metal interface layer has a thickness substantially ranging from 0.1 μm to 10 μm.

7. The ceramic/polymer composite material as claimed in claim 1, wherein the metal interface layer comprises metal material selected from the group consisting of titanium (Ti), gold (Au), titanium nitride (TiN), titanium-aluminum-vanadium alloy (Ti-6Al-4V), cobalt-chromium alloy (Co—Cr), stainless steel (SUS 316L), and titanium nitride-aluminum-vanadium.

8. The ceramic/polymer composite material as claimed in claim 1, wherein the polymer layer has an elastic modulus substantially ranging from 2 Gpa to 22 Gpa.

9. The ceramic/polymer composite material as claimed in claim 8, wherein the polymer layer comprises a polymer material and the polymer material is selected from the group consisting of polyether ether ketone (PEEK), carbon reinforced PEEK, polyetherketoneketo (PEKK), and polyaryletherketone (PAEK).

10. The ceramic/polymer composite material as claimed in claim 1, wherein the ceramic layer comprises a ceramic material having a grain size substantially ranging from 7 μm to 70 μm and selected from the group consisting of hydroxyapatite (HA), aluminum oxide (Al₂O₃), titanium oxide (TiO₂), tricalcium diphosphate (Ca₃(PO₄)₂), and zirconium oxide (ZrO₂).

11. The ceramic/polymer composite material as claimed in claim 1, wherein the ceramic layer has a density substantially ranging from 70.0% to 99% and a porosity substantially ranging from 1% to 30%.

12. A method for fabricating a ceramic/polymer composite material, comprising the steps of:
providing a polymer layer,
performing a surface process to form at least one recess on the surface of the polymer layer;
forming a metal interface layer conformally covering on the polymer layer, wherein the metal interface layer having a first surface and a second surface opposite to the first surface, and at least portions of the first surface and the second surface extending into the recess; and
forming a ceramic layer over the metal interface layer.

13. The method for fabricating a ceramic/polymer composite material as claimed in claim 12, wherein the step of performing the surface process comprises removing a part of the polymer layer to form a plurality of grooves on the polymer surface, and each groove has a depth substantially ranging from 20 μm to 100 μm.

14. The method for fabricating a ceramic/polymer composite material as claimed in claim 12, wherein the surface process comprises a sand blasting treatment to form a plurality of cavities on the polymer surface and each of the cavities has a depth substantially ranging from 1 μm to 10 μm.

15. The method for fabricating a ceramic/polymer composite material as claimed in claim 12, wherein the step of forming the metal interface layer comprises performing a deposition process to form a metal coating layer on the polymer surface extending downwards into the recess.

16. The method for fabricating a ceramic/polymer composite material as claimed in claim 15, wherein the deposition process is selected from the group consisting of physical vapor deposition (PVD), chemical vapor deposition (CVD), electroplating, electroless plating, powder plasma spraying, powder laser deposition, casting, and curing colloidal solution.

17. The method for fabricating a ceramic/polymer composite material as claimed in claim 12, wherein the step of forming the ceramic layer comprises melting a ceramic material and spraying the melted ceramic material on the metal interface layer.

18. The method for fabricating a ceramic/polymer composite material as claimed in claim 17, wherein the ceramic material selected from the group consisting of hydroxyapatite (HA), aluminum oxide (Al₂O₃), titanium oxide (TiO₂), tricalcium diphosphate (Ca₃(PO₄)₂), and zirconium oxide (ZrO₂).

19. The method for fabricating a ceramic/polymer composite material as claimed in claim 12, wherein the polymer layer comprises a polymer material selected from the group consisting of polyether ether ketone (PEEK), carbon reinforced PEEK, polyetherketoneketo (PEKK), and polyaryletherketone (PAEK).

20. The method for fabricating a ceramic/polymer composite material as claimed in claim 12, wherein the metal interface layer comprises a metal material selected from the group consisting of titanium (Ti), gold (Au), titanium nitride (TiN), titanium-aluminum-vanadium alloy (Ti-6Al-4V), cobalt-chromium alloy (Co—Cr), stainless steel (SUS 316L), and titanium nitride-aluminum-vanadium.
